(19) United States
(12) Patent Application Publication
(10) Pub. No.: US 2008/0025530 A1
(43) Pub. Date: Jan. 31, 2008

(54) Method and apparatus for normalizing sound playback loudness

(75) Inventor: Eric Douglas Romesburg, Chapel Hill, NC (US)

Correspondence Address: COATS & BENNETT/SONY ERICSSON, 1400 CRESCENT GREEN, SUITE 300, CARY, NC, 27511, US

(73) Assignee: Sony Ericsson Mobile Communications AB

(21) Appl. No.: 11/493,077

(22) Filed: Jul. 26, 2006

(51) Int. Cl. H03G 3/00; H03G 7/00

(52) U.S. Cl. 381/107; 381/106

(57) ABSTRACT

A method and apparatus for limiting an audio signal by establishing a maximum magnitude level that is responsive to a volume control and limiting a reproduced sound to that maximum allowable magnitude level. Limiting circuitry may include analog and digital solutions and may be executed through soft-limiting, hard-limiting, or a combination thereof. A limiter may include circuitry to dynamically detect peak levels in an audio signal. A desired gain may be associated with the audio signal and, if applied, produces a desired peak. This desired peak may be compared to the maximum magnitude level, which may be set relative to a peak acoustic capacity. Audio signal amplification may be set in response to this comparison, such as scaling gain by a ratio of desired peak to maximum magnitude level.

### BACKGROUND

The loudness of a given sound recording influences its perceived playback loudness. Thus, for the same playback volume setting, one sound recording may be perceived by a listener as being louder or quieter than another one. In the context of electronic devices, audible signals are used to alert users to various events. For instance, computing devices may emit a distinct tone to alert users of the arrival of new email. Ringtones are another common alert signifying an incoming call on a communications handset. As electronic devices incorporate increased functionality and customizability, different audible alerts may be used to represent different events. For example, users of communications handsets can select different ringtones to identify different callers or different events, such as incoming text or voice messages. Furthermore, voice calls or voice messages may have different loudness levels.

It is now common practice for cellular handset users to download custom ring tones to their handsets. With the proliferation of custom ring tones, handset users can change ring tones to suit their changing likes and dislikes, and can assign different ring tones to different callers. However, the characteristic loudness of different ring tone files can vary dramatically, and this results in objectionable variations in perceived ringer loudness between different ring tones for the same ringer volume setting.

Furthermore, users are no longer limited to a fixed number of audible alerts that are previously stored on the device when selecting audible alerts for particular events. To the extent an electronic device is networked or connectable to a network, users may download custom audible alerts such as digital music or sound clips from other sources (e.g., the Internet, a media player, or from a compact disc) for association with different events. Unfortunately, the sound files that are associated with different events may be obtained from different sources, created in different manners, and generally may not have uniform loudness levels. Consequently, even though a user sets a volume control level for an electronic device, the voice sounds and audible alerts may be softer or louder than desired.

### SUMMARY

Embodiments of the present invention are directed to a method and apparatus for limiting an audio signal by establishing a maximum magnitude level that is responsive to a volume control and limiting a reproduced sound to that maximum allowable magnitude level. Various implementations are possible, including analog and digital solutions. Further, the limiting may be executed through soft-limiting, hard-limiting, or a combination thereof. In one implementation, audio limiting is performed by managing gain control for an audio signal in a communications handset. The handset may include circuitry or programming to process a signal representative of a stored sound recording to determine its loudness. The loudness may be determined as one or more peak values. A limiting factor may be calculated dynamically as the value needed to prevent the signal amplified by a desired gain from exceeding a maximum magnitude limit. The maximum magnitude limit may be proportional to a volume control. For instance, the volume control may vary between zero and one and the maximum magnitude level is obtained by multiplying a peak acoustic capacity by the volume control. The limiting factor may be applied to the signal by scaling the desired gain value for the signal by the limiting factor. For example, the signal may be soft-limited by multiplying the signal's desired gain value by the limiting factor. Such processing may be applied to a stored ring tone file or other audible event alert. In one implementation, the signal may be delayed to provide look-ahead peak values.

In one implementation, the loudness normalization may be performed by a limiter comprising one or more processing circuits to process the audio signal to determine its peak value(s), dynamically calculate a limiting factor as the value needed to prevent the signal amplified by a desired gain from exceeding a maximum magnitude limit, and apply the limiting factor to the signal by scaling the desired gain value for the signal by the limiting factor. The circuitry may include a limiter control circuit to calculate the limiting factor by evaluating limiter parameters for the signal, and a scaling circuit to scale the desired gain value by the limiting factor, and applying the scaled desired gain value to the signal. More specifically, the limiter control circuit may receive limiter parameters for the signal, calculate a limiting ratio for the signal based on the limiter parameters, and set the limiting factor to the limiting ratio if the limiting ratio is less than unity or set the limiting factor to unity if the limiting ratio is greater than unity. In addition, the limiter control circuit may also receive a peak signal value, the maximum magnitude limit, and the desired gain as the limiter parameters, and calculate the limiting ratio as the ratio of the maximum magnitude limit to the product of the peak signal value and the desired gain, such that the limiting ratio is less than unity if the product of the peak signal value and the desired gain exceeds the maximum magnitude value. As indicated, the limiter may also delay the signal before scaling via the corresponding scaling circuit by a desired amount relative to peak detection, such that the peak values provided to the limiter control circuit for the signal is advanced in time relative to the signal.

Generally, an audio signal may be normalized by dynamically detecting a peak level in the audio signal, multiplying the peak level by a desired gain to determine a desired peak, setting a maximum magnitude level for the communications device as a peak acoustic capacity scaled by a volume control, comparing the desired peak to the maximum magnitude level, obtaining an actual gain by scaling the desired gain by a ratio of the maximum magnitude level to the desired peak if the desired peak exceeds the maximum magnitude level and retaining the desired gain if the maximum magnitude level exceeds the desired peak, and amplifying the audio signal using the actual gain.

The loudness normalization may be applied to a multi-channel audio signal. Accordingly, the gain for all channels may be scaled by a ratio of the maximum magnitude level to the largest desired peak corresponding to a channel having the largest peak level. Notably, each channel may include a corresponding desired gain and maximum magnitude level. That is, each channel may have the same or different desired gains, maximum magnitude levels, and desired peaks.

### BRIEF DESCRIPTION OF THE DRAWINGS

FIG. 1 is a block diagram of a limiter circuit configured to provide limiting control for an audio signal according to one or more embodiments of the present invention;

FIG. 2 is a diagram of exemplary playback limiting according to one or more embodiments of the present invention;

FIG. 3 is a block diagram of a limiter circuit configured to provide limiting control for an audio signal;

FIG. 4 is a waveform diagram illustrating the use of a time delay for look-ahead peak detection;

FIG. 5 is a logic flow diagram of processing logic for one or more embodiments of the limiting control method carried out by the limiter of FIG. 3;

FIG. 6 is a block diagram of circuit details for one embodiment of the limiter of FIG. 3;

FIG. 7 is a logic flow diagram that provides additional processing logic details for one or more embodiments of limiting control; and

FIG. 8 is a diagram of an exemplary mobile station—e.g., a cellular radiotelephone handset—that is configured according to one or more embodiments of the present invention.

### DETAILED DESCRIPTION

Before turning to the accompanying figures, it may be helpful to frame the present invention in terms of its limiting or normalization process. The present invention provides a method and apparatus for establishing a maximum audio magnitude level that is responsive to a volume control and limiting a reproduced sound to that maximum allowable magnitude. In certain embodiments, the limiting is responsive to the loudness of the audio signal, which may be processed to determine the peak values. The limiting, including either analog limiters or digital processing, may occur while the sound recordings are being reproduced, such as during an incoming call. The sound limiting may be determined for each such processed sound signal based on the signal's peak values. Consequently, the perceived playback loudness of two different audio signals having significantly different peak levels is made substantially the same by limiting the playback loudness used for each recording according to the maximum magnitude level.

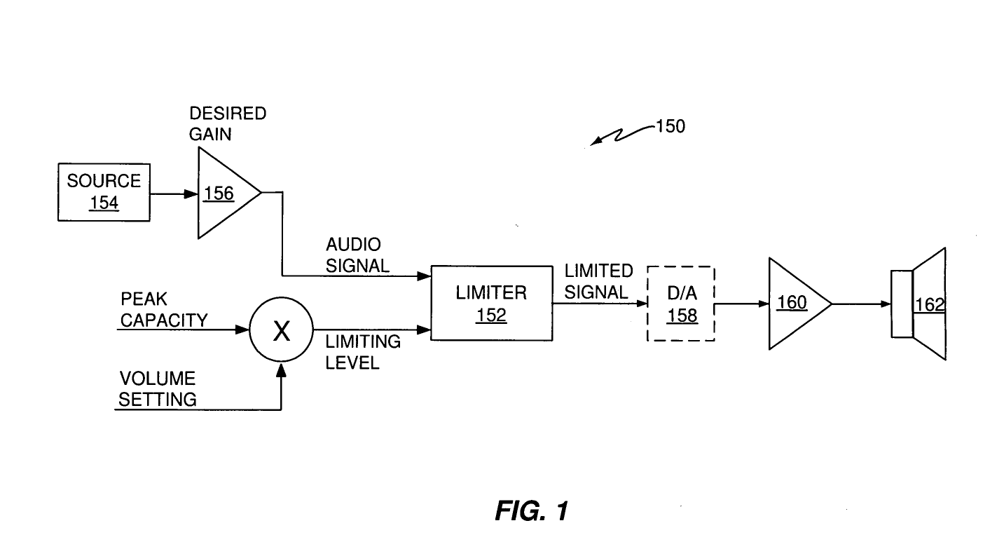

With the above technique in mind, FIG. 1 functionally illustrates exemplary circuitry 150 to execute the limiting process generally described above. The circuitry 150 represents a limiter that may be implemented in hardware or software. Generally, the circuitry 150 includes a signal limiter 152 that provides limiting control for an audio signal. The signal limiter 152 may be implemented for use with a single channel or for use with multi-channel audio signals as described herein. The limiter 152 is configured to threshold or soft-limit the audio signal to prevent the input audio signal from exceeding a limiting level that is determined as some combination of a peak acoustic capacity and a volume control. As suggested below, the limiting level may be scaled by the volume control, proportional to the volume control, or otherwise responsive to the volume control. Once established, the limiter 152 limits the audio signal, such as through scaling or clipping, to the extent the audio signal exceeds the limiting level.

The audio signal is provided from a source 154 that may include stored audio files, stored voice messages, real-time audio signals, including voice transmissions, and other sources as described herein and as are known in the art. A desired gain is applied at amplifier 156 and the amplified audio signal is limited by the limiter 152. For software implementations, the limited audio signal may be converted by D/A circuits 158. Note that in hardware implementations, the D/A circuits 158 are not applicable. Hence, the D/A circuits 158 are depicted in a dashed line representation. Finally, the limited signal may be further processed, such as by additional amplifier circuits 160 for playback by speakers 162.

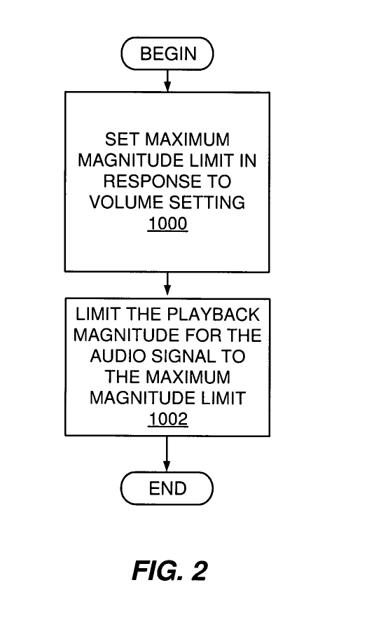

FIG. 2 illustrates exemplary processing logic that outlines this method of audio limiting. Such processing logic can be implemented in hardware, software, or any combination thereof. In one embodiment, the processing logic of system 150 is implemented as computer program instructions for execution by a microprocessor, or the like. Such instructions may be implemented as software, firmware, or microcode. In other embodiments, the processing logic is implemented in hardware, such as an Application Specific Integrated Circuit (ASIC), a Field Programmable Gate Array (FPGA), a Complex Programmable Logic Device (CPLD), or the like. Regardless, some type of processing circuit, whether hardware, software, or some combination thereof, may be used to implement the present invention.

The exemplary processing steps shown in FIG. 2 generally illustrate an exemplary technique that may be implemented using the limiter embodiments disclosed herein or other known types of limiters. Regardless of the particular implementation details, processing begins at step 1000 with setting a maximum magnitude limit in response to a volume control setting. The maximum magnitude limit may be based upon a peak volume capacity for the system with the volume scaling the maximum magnitude limit between zero or some small number and the peak volume capacity. However, in other implementations, the maximum magnitude limit may be obtained via some other relation between the peak volume capacity and the volume control. For instance, maximum magnitude limits may be logarithmically or exponentially related to a volume control. In another implementation, maximum magnitude limit may be established through a look-up table, with certain discrete volume settings having retrievable corresponding maximum magnitude limits. Those skilled in the art will appreciate other approaches for varying the maximum magnitude limit in response to the volume control.

Then, at step 1002, the system can limit the audio reproduction loudness using the maximum magnitude limit as a desirable peak value for the output. As disclosed above, the limiting may be implemented via soft-limiting. This may be accomplished by attempting to amplify an audio signal up to a desired gain in an effort to synchronize a peak in the audio signal with the maximum magnitude limit. In another implementation, the signal may be hard limited to the maximum magnitude limit without any corresponding amplification. In another implementation, the audio signal may be amplified using a desired gain and then hard limited to the extent the amplified signal exceeds the maximum magnitude limit. Further, those skilled in the art will recognize that the various implementations may be executed in either the analog or digital domains or some combination thereof.

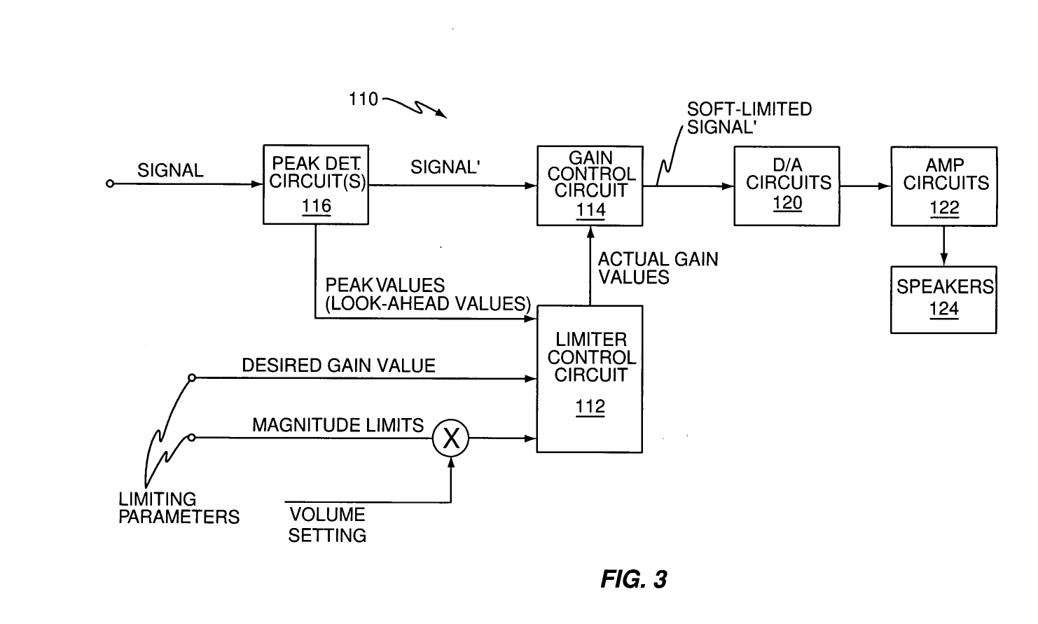

In the context of FIG. 3, audio limiting may occur in the digital domain, which may be a convenient approach if the source sound recording is a digital audio file. Thus, a limiter control circuit 112 effectively may adjust its nominal gain as determined by the volume control input up or down as a function of the appropriate gain control based upon the recording loudness. That adjustment may be based on mathematically scaling the digital (amplitude) values of the sound recording up or down. If the determined gain control is calculated with respect to the “full scale” value of the sound recording, the gain adjustment will be inherently appropriate for the (digital) amplitude range of the sound file. Note, too, that the gain setting fixed by the determined gain compensation for playback of the sound recording can be set separately from the gain setting fixed by the currently selected volume setting. In this case, two gain control circuits may be placed in series, for example, with one controlled by the determined gain control, and one controlled by the volume control input.

The gain compensation may be determined with a signal limiter as shown in FIG. 3. A similar limiter is disclosed in commonly assigned, co-pending U.S. patent application Ser. No. 11/071,683, filed Mar. 3, 2005, the contents of which are hereby incorporated by reference herein. Specifically, FIG. 3 functionally illustrates one embodiment of a signal limiter 110 that provides limiting control for a single-channel audio signal. The signal limiter 110 may be expanded for use with multi-channel audio signals as described below. The limiter 110 shown in FIG. 3 is configured to set a “limiting factor” dynamically to whatever value is needed to prevent the input audio signal from exceeding defined magnitude limits. In other words, the limiter 110 determines a gain reduction for the signal to prevent the signal from clipping.

The limiter 110 performs signal limiting based on the application of a limiting factor that dependent upon two limiting parameters: Desired Gain Values and Magnitude Limits. These values are generally application specific and depend upon such factors as transducer sensitivity, efficiency, and anticipated distance to a listener's ear. The Magnitude Limit represents the loudest permissible loudness for the given system. Again, this may be based, in part, on such factors as speaker size or safety measures. The Desired Gain Value represents the desired amount of amplification for the system and may be based, in part, on such factors as the volume of loaded sound files and speaker orientation or other speaker characteristics. Thus, the limiter 110 will generally attempt to amplify an input signal by an amount up to the Desired Gain Value to make the output signal equal to the Magnitude Limit. However, if the input signal is relatively loud, the amount of applied gain will be scaled downward appropriately.

To achieve these effects, the illustrated limiter 110 comprises a limiter control circuit 112 for generating actual gain values for the input signal based on the aforementioned limiting factor. The limiter 110 further includes a gain control circuit 114 for applying the actual gain values to the signal. The limiter 110 further includes, or is at least associated with, a peak detection circuit 116 that provides peak detection for the input signal, referred to as the “Signal.” The limiter 110 further may be associated with one or more output circuits that are driven by the (soft) limited version of the signal provided by the limiter 110. In an audio signal context, such circuits may comprise digital-to-analog converters (D/As) 120, amplifier circuits 122, and speakers 124.

For example, in the illustrated context, the limiter 110 dynamically detects peak values, determines whether the detected peak value(s) will violate maximum magnitude limits given current desired gain settings and, if so, makes an appropriate adjustment to the actual gain value to prevent such violations. The limiter 110 thus provides a soft-limited version of the Signal to the D/As 120, which in turn provide the amplifier circuits 122 with corresponding analog signals that are then power-amplified and used to drive the loudspeakers 124.

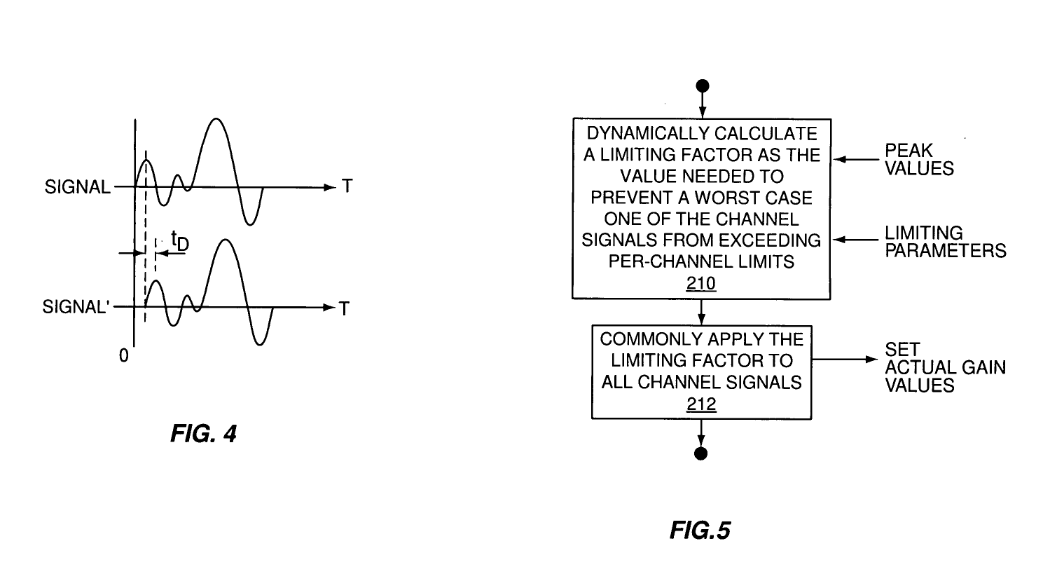

In more detail, the Signal passes through the peak detection circuit 116, which provides peak detection values to the limiter control circuit 112. The peak detection circuit 116 may also provide a delayed version of the Signal to the gain control circuit 114, though this is not expressly required. In FIG. 3, a delayed version of the Signal is denoted as Signal′, though it should be understood that the gain control may be implemented on the non-delayed Signal. Providing the gain control circuit 114 with the delayed version of the Signal effectively “advances” the peak detection function in time relative to gain control, allowing the limiter control circuit 112 to “see” peak values in the Signal before those peaks arrive at the input of the gain control circuit 114. In other words, by advancing peak detection, i.e., by providing the limiter control circuit 112 with “look-ahead” peak values, the limiter control circuit 112 can detect impending signal limit violations and adjust the actual gain applied by the gain control circuit 114 by updating the limiting factor to prevent such violations from occurring. FIG. 4 illustrates an exemplary time delay, t_{D}, imposed on Signal′ relative to Signal, which allows peak detection to operate on Signal in advance of gain control being imposed on Signal′.

In an exemplary embodiment, the “look-ahead” time for peak detection may be set to a value at or about one-quarter cycle time of the lowest signal frequency of interest in the Signal. For example, if the Signal is an audio signal, the lowest frequency of interest might be 20 Hz. A 20 Hz signal has a cycle time of 50 ms, and one-quarter of that cycle time is 12.5 ms. Thus, the peak detection circuit 116 can be configured to delay the Signal′ by about 12.5 ms. Of course, advances other than one-quarter cycle time can be used as needed or desired.

In any case, the limiter control circuit 112 receives peak values for the Signal, and additionally receives the Desired Gain and Magnitude Limit parameters. The limiter control circuit 112 determines a limiting factor that is a bounded, unitless multiplier that is applied to the Desired Gain parameter. Specifically, the limiting factor LF for the Signal is determined as:

$$LF = min ( 1 , \frac{Magnitude Limit}{Desired Gain \times Peak Value} ) \qquad ( 1 )$$

where Magnitude Limit and Desired Gain are the input parameters described above and Peak Value is the peak value detected by the peak detection circuit 116. Notably, the limiting factor LF is bounded between 0 and 1. Then, the Actual Gain applied to the input Signal (or delayed Signal′) is given by:

ActualGain=LF*Desired Gain (2)

The practical effects of equations (1) and (2) may be understood by recognizing that the denominator (Desired Gain×Peak Value) represents an amplified peak value where the entire Desired Gain is applied to the input Signal. If the amplified peak value is less than the Magnitude Limit, the limiting factor LF is set to 1. This means the entire Desired Gain is actually applied. Otherwise, if the amplified peak value is larger than the Magnitude Limit, then some smaller value should be applied. In fact, the ratio of the Magnitude Limit and the amplified peak value is used as the limiting factor LF. Consequently, the Actual Gain may be applied to the input Signal to produce an output with peak values that equal the Magnitude Limit.

As suggested above, the Magnitude Limit may account for various design constrains such as transducer or speaker size, sensitivity, and anticipated distance to the listener. Such considerations may be considered design-time constraints. In one implementation, the Magnitude Limit may include run-time constraints. One embodiment may account for a volume control that is set by the individual end-user. The volume control may include a master volume control that sets an overall system volume. Different volume controls may exist for different functions, including for example system sounds, loudspeaker playback, or earpiece playback. In any event, the volume may be established as some value that varies between zero and one as determined by the user. This volume may be set using UP-DOWN arrows, a dial, or other menu selection. In any event, the Magnitude Limit may be expressed as:

Magnitude Limit=Peak Acoustic Capacity*User Volume (3)

where the Peak Acoustic Capacity represents design-time constraints such as those described above and the User Volume represents run-time constraints. The Peak Acoustic Capacity may be considered an absolute maximum loudness limit that is scaled by the user volume. Thus, the limiter control circuit 112 may use the Magnitude Limit for calculating the limiting factor and the actual gain in a single process step.

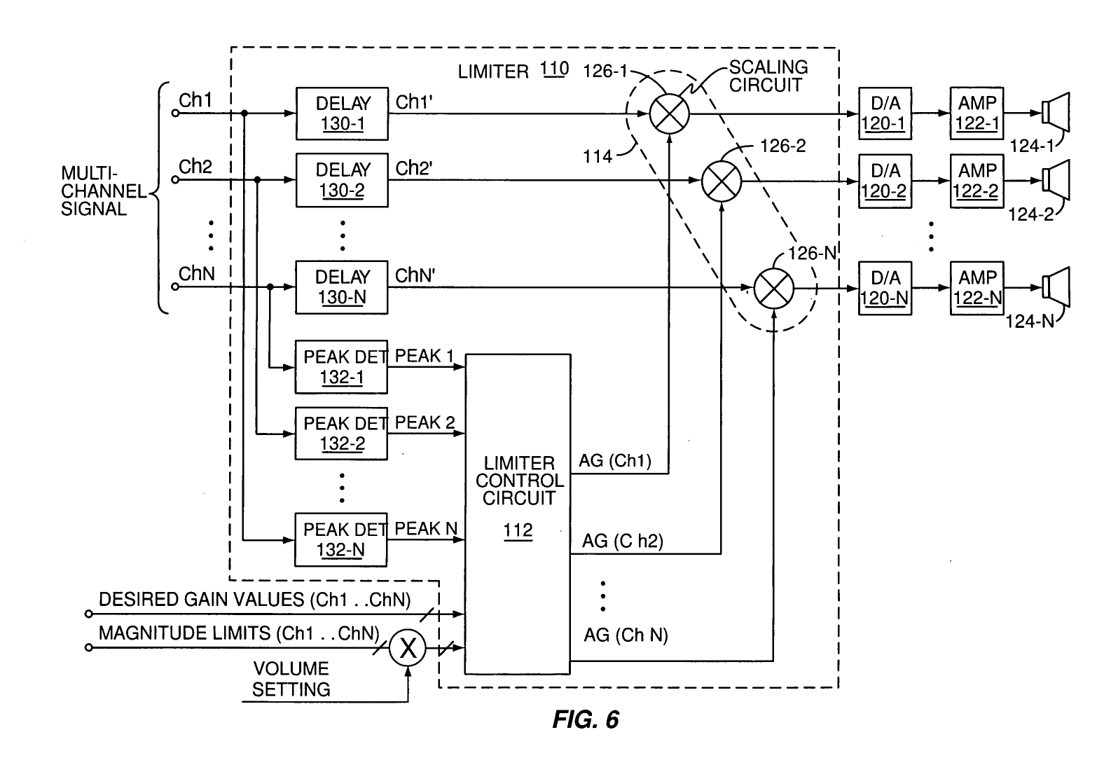

Also as suggested above, the signal limiter 110 may be expanded for use with multi-channel audio signals. FIG. 5 broadly illustrates the coordinated, multichannel gain control of limiter 110 for multichannel applications as shown in FIG. 6. Limiting control comprises dynamically calculating the limiting factor as the value needed to prevent a “worst-case” one of the channel signals in the multi-channel signal (MCS) from exceeding its per-channel limits (Step 210). Processing continues with the limiter control circuit 112 updating the actual gain values for each channel signal by scaling the per-channel desired gain values by a limiting factor (Step 212). A common limiting factor may be applied for each channel. Also note that the use of “per-channel” in this context denotes that each channel signal in the MCS may have different desired gain settings and/or different magnitude limits, but it should be understood that the same limiter parameters may be used for any number of channel signals in the MCS. Furthermore, it should be noted that the desired gain and/or peak acoustic capacity values used in establishing actual gain values may be fixed quantities that are determined in part by variables described above, including for example speaker size or safety measures. In one embodiment, the desired gain and/or peak acoustic capacity values are variable quantities. As a non-limiting example, desired gain and/or peak acoustic capacity can dynamically change as an accessory such as an external speaker is connected or disconnected.

In one embodiment, the limiter 110 performs signal limiting based on the application of a common limiting factor even where the limiter parameters, e.g., the maximum magnitude limit, the desired channel gain, and the current peak value, differ between two or more of the channel signals comprising the MCS. As such, the limiter 110 can be applied advantageously in systems or devices where the channel signals have different magnitude limits, or different desired gains. By way of a non-limiting examples, a mobile communication device having differently sized left and right speakers, or having one speaker naturally closer to a user's ear than the other one, represent circumstances where one might expect the left and right channels of a stereo signal to have different maximum magnitude limits and/or different desired gain values.

By way of additional non-limiting examples, in the audio context, different audio channel signals may have different desired gain values and/or different magnitude limits because of non-centered balance control settings, because the different channel signals are used to drive different sizes of loudspeakers (after amplification), because of the need to tailor the generated sound field to a particular listener's position, or because the listener is presumed to be closer to one speaker than another. That last case may be a particular consideration in cellular telephones, Push-To-Talk handsets, or other types of communication handsets, portable music devices, etc., where the nature of the device generally requires the user to position one loudspeaker closer to his or her ear(s).

In at least one embodiment, the limiter 110 dynamically calculates the common limiting factor (LF) as:

$$LF = min ( \begin{matrix}1 , \frac{Mag . Limit ( Ch 1 )}{Des . Gain ( Ch 1 ) \times Peak Value ( Ch 1 )} , … , \\ \frac{Mag . Limit ( ChN )}{Des . Gain ( ChN ) \times Peak Value ( ChN )}\end{matrix} ) \qquad ( 4 )$$

which is similar to Eq. 1, but expanded for multiple channels. One sees that the limiter 110 maintains the limiting factor at whatever value is needed to prevent clipping, saturation, etc., on any of the channel signals within the MCS. More particularly, a “limiting ratio” (LR) is calculated for each channel signal in the MCS as the ratio of the channel signal's maximum magnitude value (limit) to the product of the channel signal's current peak value measurement and the channel signal's current desired gain value. Thus, Eq. 1 can be written as:

LF=min(1,LR(Ch1),LR(Ch2), . . . ,LR(ChN)). (5)

With the simplified notation of Eq. 5, one sees that the limiting factor is set to unity if none of the limiting ratios is less than unity, or is set to a lowest one of the limiting ratios is any of them is less than unity. Those skilled in the art will recognize that a limiting ratio of 1 represents a channel signal that is on the verge of exceeding its defined magnitude limits, i.e., the product of its desired gain and its current peak value exactly equals its maximum allowed magnitude.

FIG. 6 illustrates the limiter 110 in more detail and, in particular, illustrates one method of commonly applying the limiting factor to all of the channel signals in the MCS. As illustrated, the gain control circuit 114 comprises a one or more scaling circuits 126, e.g., scaling circuit 126-1 for gain controlling Ch1 of MCS′, scaling circuit 126-2 for scaling Ch2 of MCS′, and so on. Thus, each channel signal is scaled by a corresponding actual gain value (AG) that is a product of that channel signal's desired gain value (DG) and the limiting factor (LF). Mathematically, the actual gain value applied to the ith channel signal=DG(Chi)×LF.

Also, the illustrated embodiment of the peak detection circuit 116 comprises delay circuits 130-1 through 130-N for delaying respective ones of the channel signals Ch1 through ChN, to produce the delayed signal, MCS′, for input to the scaling circuits 126 of gain control circuit 114. As indicated above, the delay circuits 130 advantageously provide look-ahead peak detection, but are not expressly required. Peak detection circuit 116 further includes peak detectors 32-1 through 32-N to generate peak value measurements for channel signals Ch1 through ChN.

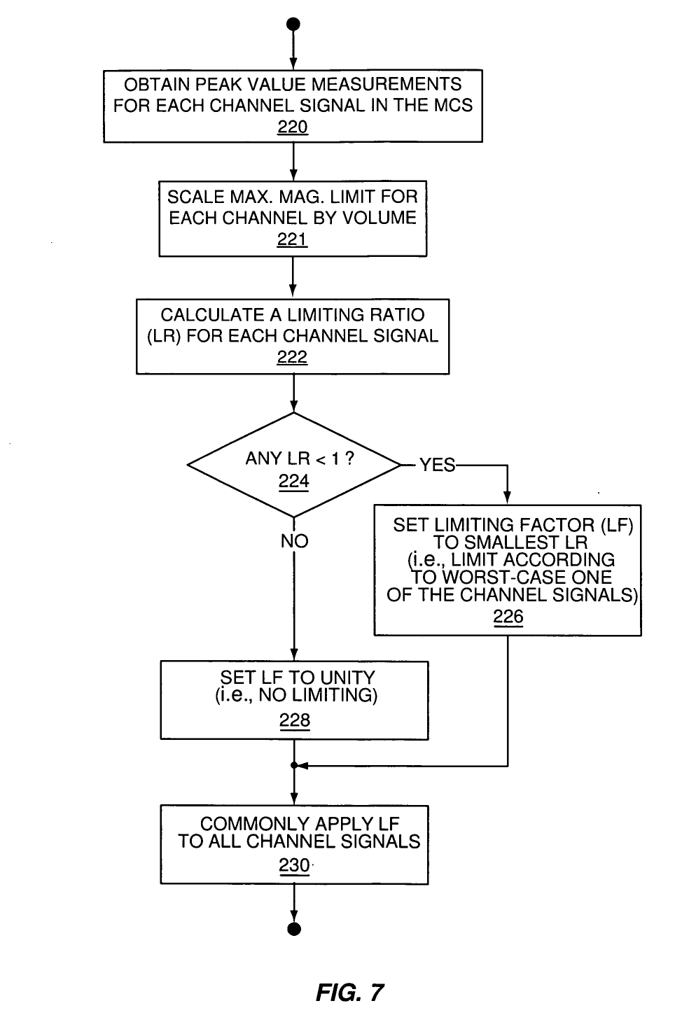

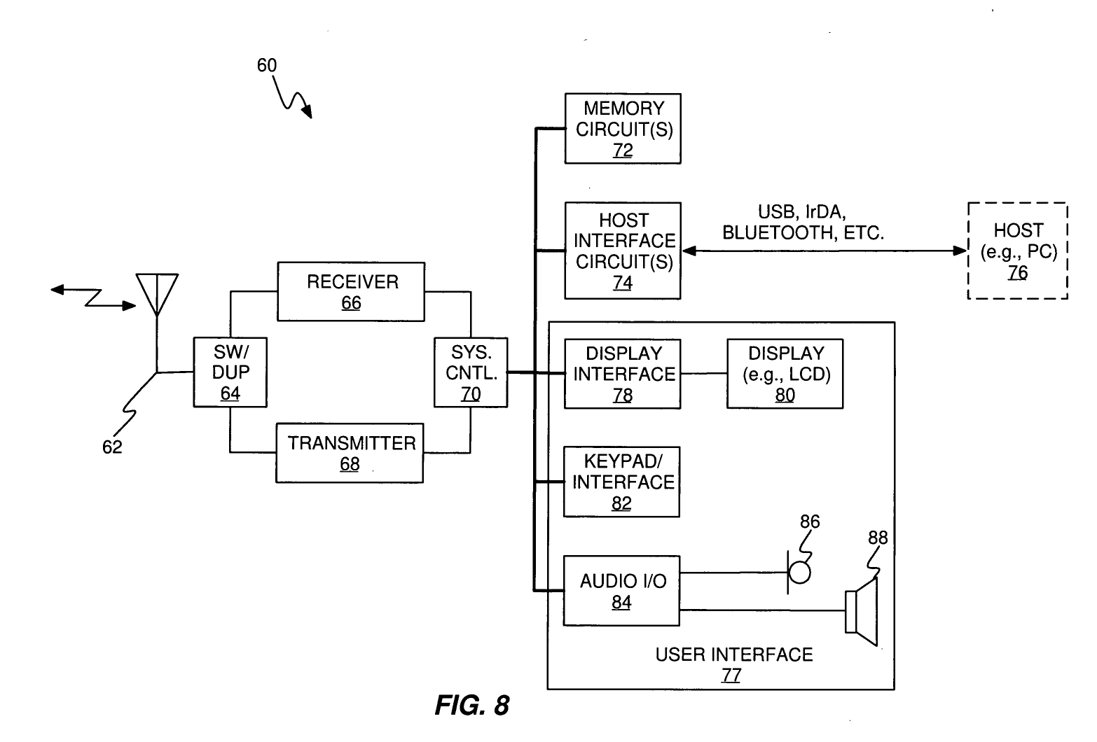

FIG. 7 illustrates limiting control based on the implementation of Eq. 4 or 5. Processing begins with the limiter 110 obtaining look-ahead peak value measurements for each channel signal in the MCS (Step 220), and calculating a limiting ratio for each channel signal (Step 222), e.g., the limiting ratio for the ith channel signal=LR(Chi)=Mag. Limit (Chi)/(DG(Chi)×PV(Chi), where DG equals the desired gain setting and PV equals the current peak value. Note that the Mag. Limit. is scaled by a volume setting as indicated by step 221. Also note that the denominator in this ratio represents an amplified peak value that would result if the full desired gain is applied to the channel signal as described above.

Processing continues with the evaluation of the limiting ratios for all channel signals to determine whether any of them are less than unity (Step 224). If so, the limiting factor is set to the smallest one of the limiting ratios (Step 226), i.e., to the lowest fractional value, which corresponds to the worst-case one of the channel signals. If none of the limiting ratios is less than unity, then the limiting factor's value is set to unity (Step 228). In either case, the limiting factor is applied to all channel signals, such that any gain scaling needed to prevent clipping on any of the channel signals is commonly applied across all channel signals comprising the MCS (Step 230).

Further, while it should be understood that the playback loudness normalization method of the present invention can be advantageously applied in essentially any kind of device or system that plays back stored sound recordings, or manages the playback of such recordings, the present invention may have particular advantages in certain contexts. For example, FIG. 8 illustrates an exemplary wireless communication device 60, which may be a cellular radiotelephone, wireless pager, Portable Digital Assistant (PDA) with communication capabilities, or the like. Thus, its implementation details may vary as a function of its intended purpose (or purposes), but the exemplary device 60 is configured to carry out the present invention's method of playback loudness normalization for at least some of the sound recordings stored by device 60.

While not every functional element illustrated relates to supporting the particular signal processing comprising the present invention, the exemplary device 60 comprises a transmit/receive antenna assembly 62, a switch/duplexer 64, a radiofrequency (RF) transceiver comprising a receiver 66 and a transmitter 68, a system controller 70, one or more memory circuits 72, a host interface 74 to communicate with a host system 76 (e.g., a PC), and an user interface 77. An exemplary user interface 77 comprises a display interface 78 and a display 80, which may be a graphics-capable color LCD or other screen type, a keypad interface and keypad 82, and an audio input/output subsystem 84. The audio subsystem 84 may be connected to an audio input transducer 86 (e.g., a microphone) and to an audio output transducer 88 (e.g., a speaker).

The present invention, which may comprise hardware, software, or both, may be implemented in system controller 70. An exemplary system controller 70 comprises one or more microprocessors and/or other processing circuits, and supporting circuits, as needed. Thus, system controller 70 may be configured to read a sound recording from memory circuit(s) 72 over a data bus, for example, process the sound recording to determine its peak values and a corresponding gain control, and then write the gain control as a parameter to memory circuit(s) 72 for later use in normalizing the playback loudness of the sound recording responsive to it being selected for playback. Of course, the actual gain control can be determined for selected sound recording on the fly, and held in working memory for immediate loudness normalization of the selected sound recording.

In terms of obtaining sound recordings, device 60 may “download” sound recordings via wireless signaling with a supporting wireless communication network using receiver 66 and transmitter 68, and/or it may download sound recordings from a local host 76 via host interface circuit(s) 74. Host interface circuit(s) 74 may include essentially any type of local communication interface circuit. By way of non-limiting examples, the host interface circuit(s) 74 may comprise one or more of the following: a Universal Serial Bus (USB) interface, an IEEE 1394 (Firewire) interface, an infrared (e.g., IrDA) interface, and a short-range radio interface (e.g., Bluetooth, 802.11, etc.).

Note, too, that the audio subsystem 84 may comprise a microprocessor or other (possibly dedicated) processing circuit that can be configured to carry out exemplary playback loudness normalization in accordance with the present invention. Indeed, the present invention can be implemented using relatively modest processing resources, and is practically implemented using inexpensive programmable or custom logic circuits. Thus, the present invention may be commercially embodied in the form of pre-programmed or pre-configured integrated circuit devices, as software for execution on specified microprocessor/microcontroller cores, and/or as digital synthesis files for use with Electronic Design Automation (EDA) tools of the type used to design integrated circuits.

For digital domain implementations of limiter 110, the magnitude limit for each channel can be expressed as a maximum count value, e.g., a not-to-exceed count value corresponding to the input count range of the D/As being used to generate analog signals from the soft-limited channel signals. Similarly, the desired and actual gain values can be integer or real-valued numbers used to scale the digital values comprising the channel signals of the MCS.

With a full-digital implementation, the limiter 110 may comprise hardware, software, or any combination thereof. For example, the limiter 110 may be implemented in stored program instructions for execution by a microprocessor, DSP, or the like, and it may be integrated with other processing functionality. For example, the limiter 110 may be functionally implemented in a microprocessor or other processing circuit that performs one or more additional functions related to the operation of the device 60. Of course, the limiter 110 is not limited to digital domain processing, and it should be understood that the limiter 110 can be implemented in whole or in part in the analog domain.

Also, regardless of whether the limiter 110 is configured for digital, analog, or mixed digital/analog processing, it should be understood that the processing methods illustrated in FIGS. 5 and 7, for example, generally represent a dynamic process that updates the limiting factor on an ongoing basis and/or as needed. For example, the peak detection circuit 116 may update its peak value measurements on a periodic basis, and the limiter 110 can recalculate the limiting factor at least as often as new peak value measurements are provided to it. More specifically, peak detection circuit 116 may detect peak values for an entire audio file or for temporal windows of an audio signal. Thus, it should be understood that peak detection may be calculated globally or locally, depending upon the size of the temporal windows.

In addition, the limiter 110 may make as-needed recalculations of the limiting factor responsive to changes in the limiter parameters. For example, the desired gain settings or magnitude limits of one or more of the channel signals may change from time to time, such as in audio playback applications where a user may adjust volume and/or balance settings, and the limiter 110 can recalculate the limit factor responsive to such changes. Also, it should be understood that the maximum magnitude limits may be set explicitly for any one or more of the channel signals comprising the multichannel signal, or may be implicit limits, such as full-scale analog and/or digital range limitations, which can be different for individual ones of the channel signals.

Significant flexibility exists regarding the applications in which the present invention may be used. In one exemplary embodiment, a portable communication device, such as a mobile station, pager, Portable Digital Assistant (PDA), or the like, is configured to normalize the playback loudness of stored ring tones. In other words, for a given ringer volume setting, operation of the present invention eliminates (or at least reduces) potentially objectionable variations in the perceived loudness of different ring tones or event alerts. Such operation is particularly beneficial where a user's communication device is configured to use different ring tones for different Caller IDs, etc.

The present invention has broad applicability beyond the ring tone and event alert normalization. Its loudness normalization processing can, for example, be applied to digital music libraries comprising digital audio files potentially obtained from different sources and potentially subject to wide variations in recorded loudness. Thus, music player software on a Personal Computer (PC), or on a digital media server accessible via the Internet, may be configured to limit audio playback in the manner described herein. Playback loudness limiting may be implemented with voice audio signals, real time, such as during a voice call conversation or when retrieving a voice message.

Accordingly, the present invention is not limited to the above features and advantages and may be carried out using different techniques that those explicitly described herein. The present embodiments are, therefore, to be considered in all respects as illustrative and not restrictive, and all changes coming within the meaning and equivalency range of the appended claims are intended to be embraced therein.

What is claimed is:

1. A method of normalizing sound playback loudness for an audio signal, the method comprising:
setting a maximum magnitude limit responsive to a volume control, the maximum magnitude limit being relative to a peak acoustic capacity;
limiting the audio signal to prevent the signal from exceeding the maximum magnitude limit; and
acoustically reproducing the limited audio signal.

2. The method of claim 1 wherein the step of limiting the audio signal to prevent the signal from exceeding the maximum magnitude limit comprises soft-limiting the audio signal.

3. The method of claim 1 wherein the step of limiting the audio signal to prevent the signal from exceeding the maximum magnitude limit comprises hard-limiting the audio signal.

4. The method of claim 1 wherein the step of limiting the audio signal to prevent the signal from exceeding the maximum magnitude limit comprises amplifying the audio signal by an amount less than or equal to a desired gain to match a peak level in the audio signal to the maximum magnitude limit.

5. The method of claim 1 wherein the audio signal includes multiple channels and the step of limiting the audio signal to prevent the signal from exceeding the maximum magnitude limit further comprises limiting each channel to a common maximum magnitude limit.

6. The method of claim 5 wherein the step of limiting the audio signal to prevent the signal from exceeding the maximum magnitude limit further comprises preventing a peak of the multiple channels from exceeding the maximum magnitude limit.

7. A method of normalizing sound playback loudness for an audio signal, the method comprising:
processing the audio signal to determine its peak;
setting a maximum magnitude limit responsive to a volume control, the maximum magnitude limit being relative to a peak acoustic capacity;
determining a maximum gain allowable to prevent the audio signal amplified by the maximum gain from exceeding the maximum magnitude limit; and
amplifying the audio signal using the maximum gain.

8. The method of claim 7 wherein the step of determining a maximum gain allowable to prevent the audio signal amplified by the maximum gain from exceeding the maximum magnitude limit further comprises aligning a detected peak level in the audio signal with the maximum magnitude limit.

9. The method of claim 7 wherein the step of determining a maximum gain allowable to prevent the audio signal amplified by the maximum gain from exceeding the maximum magnitude limit further comprises scaling a desired gain for amplifying the audio signal.

10. The method of claim 7 wherein the audio signal includes multiple channels and the step of amplifying the audio signal using the maximum gain further comprises amplifying each channel by a common maximum gain.

11. The method of claim 7 wherein the audio signal includes multiple channels and the peak comprises the peak of the multiple channels.

12. A method of managing gain control for an audio signal in a communications handset, the method comprising:
processing the audio signal to determine its peak;
setting a maximum magnitude limit responsive to a volume control, the maximum magnitude limit being relative to a peak acoustic capacity;
dynamically calculating a limiting factor as the value needed to prevent the signal amplified by a desired gain from exceeding a maximum magnitude limit; and
scaling the desired gain value for amplifying the audio signal by the limiting factor.

13. The method of claim 12, wherein scaling the desired gain value for the signal by the limiting factor comprises soft-limiting the signal by multiplying the signal's desired gain value by the limiting factor.

14. The method of claim 12, wherein the volume control varies between zero and one and the step of setting the maximum magnitude limit further comprises multiplying an absolute maximum magnitude level by the volume control.

15. The method of claim 12, wherein processing the audio signal to determine its peak comprises, at a wireless communication handset, processing a stored ring tone file.

16. The method of claim 12, wherein dynamically calculating a limiting factor as the value needed to prevent the signal amplified by a desired gain from exceeding a maximum magnitude limit comprises:
calculating a limiting ratio for the signal as the ratio of the maximum magnitude limit to the product of a current peak value detected for the signal and the desired gain; and
setting the limiting factor to unity if the limiting ratio is greater than unity, and setting the limiting factor to the limiting ratio if the limiting factor is less than unity.

17. The method of claim 12, wherein the step of processing the audio signal to determine its peak further comprises delaying the signal and providing look-ahead peak values.

18. The method of claim 12 wherein the audio signal includes multiple channels and the step of scaling the desired gain value for amplifying the audio signal by the limiting factor further comprises scaling the desired gain for each channel by a common limiting ratio.

19. The method of claim 12 wherein the audio signal includes multiple channels and the peak comprises the peak of the multiple channels.

20. A method of limiting an audio signal in a communications device comprising the steps of:
dynamically detecting a peak level in the audio signal;
multiplying the peak level by a desired gain to determine a desired peak;
setting a maximum magnitude level for the communications device as a peak acoustic capacity scaled by a volume control;
comparing the desired peak to the maximum magnitude level;
obtaining an actual gain by scaling the desired gain by a ratio of the maximum magnitude level to the desired peak if the desired peak exceeds the maximum magnitude level and retaining the desired gain as the actual gain if the maximum magnitude level exceeds the desired peak; and
amplifying the audio signal using the actual gain.

21. The method of claim 20, wherein the audio signal is a multi-channel audio signal and the step of scaling the desired gain by a ratio of the maximum magnitude level to the desired peak if the desired peak exceeds the maximum magnitude level further comprises scaling the gain for all channels by a ratio of the maximum magnitude level to the largest desired peak corresponding to a channel having the largest peak level.

22. The method of claim 21 wherein each channel includes a corresponding desired gain and maximum magnitude level.

23. The method of claim 20, wherein the volume control varies between zero and one and the maximum magnitude level is obtained by multiplying the peak acoustic capacity by the volume control.

24. The method of claim 20, wherein dynamically detecting a peak level in the audio signal comprises, at a wireless communication handset, processing a stored ring tone file.

25. The method of claim 20, further comprising delaying the signal and providing look-ahead peak levels prior to amplifying the signal.

26. A limiter for limiting an audio signal, the limiter comprising one or more processing circuits configured to:
process the audio signal to determine its peak;
set a maximum magnitude limit responsive to a volume control, the maximum magnitude limit being relative to a peak acoustic capacity;
limit the audio signal to prevent the signal from exceeding the maximum magnitude limit; and
reproduce the limited audio signal.

27. The limiter of claim 26, wherein the one or more processing circuits comprise a limiter circuit to threshold the audio signal at the maximum magnitude limit and prevent the signal from exceeding the maximum magnitude limit.

28. The limiter of claim 26, wherein the one or more processing circuits comprise a limiter circuit to determine a maximum gain allowable to prevent the audio signal amplified by the maximum gain from exceeding the maximum magnitude limit, and amplifying the audio signal using the maximum gain.

29. The limiter of claim 26, wherein the signal comprises a multichannel audio signal and the one or more processing circuits determine a peak for each channel and further apply a common maximum magnitude limit to each channel.

30. The limiter of claim 29 wherein the signal comprises a multichannel audio signal and the peak comprises a peak of the multiple channels.

31. A limiter for limiting an audio signal in a communications device, the limiter comprising one or more processing circuits configured to:
process the audio signal to determine its peak;
set a maximum magnitude limit responsive to a volume control, the maximum magnitude limit being relative to a peak acoustic capacity;
dynamically calculate a limiting factor as the value needed to prevent the signal amplified by a desired gain from exceeding a maximum magnitude limit; and
apply the limiting factor to the signal by scaling the desired gain value for amplifying the audio signal by the limiting factor.

32. The limiter of claim 31, wherein the volume control varies between zero and one and the maximum magnitude level is set by multiplying an absolute maximum magnitude level by the volume control.

33. The limiter of claim 31, wherein the one or more processing circuits comprise a limiter control circuit to calculate the limiting factor by evaluating limiter parameters for the signal, and a scaling circuit to scale the desired gain value by the limiting factor, and applying the scaled desired gain value to the signal.

34. The limiter of claim 31, wherein the one or more processing circuits comprise a limiter control circuit configured to calculate the limiting factor, and a scaling circuit to scale the signal by the limiting factor, said limiter control circuit configured to receive limiter parameters for the signal, calculate a limiting ratio for the signal based on the limiter parameters, and set the limiting factor to the limiting ratio if the limiting ratio is less than unity or set the limiting factor to unity if the limiting ratio is greater than unity.

35. The limiter of claim 34, wherein the limiter control circuit is configured to receive a peak signal value, the maximum magnitude limit, and the desired gain as the limiter parameters, and to calculate the limiting ratio as the ratio of the maximum magnitude limit to the product of the peak signal value and the desired gain, such that the limiting ratio is less than unity if the product of the peak signal value and the desired gain exceeds the maximum magnitude value.

36. The limiter of claim 35, wherein the limiter is configured to delay the signal before scaling via the corresponding scaling circuit by a desired amount relative to peak detection, such that the peak values provided to the limiter control circuit for the signal is advanced in time relative to the signal.

37. The limiter of claim 31, wherein the signal comprises a multichannel audio signal.

38. The limiter of claim 37, wherein the one or more processing circuits determine a peak for each channel and further apply a common limiting factor to each channel.

39. The limiter of claim 37, wherein the peak comprises a peak of the multiple channels.
